(19) United States
(12) Patent Application Publication
(10) Pub. No.: US 2025/0105205 A1
(43) Pub. Date: Mar. 27, 2025

(54) LAMINATE MANUFACTURING METHOD AND LAMINATE

(71) Applicant: Resonac Corporation, Minato-ku, Tokyo (JP)

(72) Inventors: Yuki IMAZU, Minato-ku, Tokyo (JP); Kazuyuki MITSUKURA, Minato-ku, Tokyo (JP)

(21) Appl. No.: 18/716,993

(22) PCT Filed: Dec. 8, 2021
(86) PCT No.: PCT/JP2021/045160

§ 371 Date: Dec. 9, 2024

(51) Int. Cl. H01L 23/00

(52) U.S. Cl. CPC H01L 24/80; H01L 24/03; H01L 24/08; H01L 2224/03845; H01L 2224/08145; H01L 2224/80895; H01L 2224/80896

(57) ABSTRACT

A method for manufacturing a laminate includes forming a first organic insulating layer including a first thermosetting resin and first inorganic oxide particles on a first support substrate, polishing a first surface of the first organic insulating layer to planarize the first surface, and bonding the polished first surface to a second surface of a second organic insulating layer including a second thermosetting resin and second inorganic oxide particles.

### TECHNICAL FIELD

The present disclosure relates to a method for manufacturing a laminate and a laminate, for example, to a method for manufacturing a laminate (semiconductor device) including a semiconductor chip, and a laminate including a semiconductor chip.

### BACKGROUND ART

As a method for connecting connection terminals in the connection of semiconductor chips laminated in a vertical direction or the connection of a semiconductor package such as a silicon interposer and semiconductor chips, various methods of direct bonding technique for directly bonding the connection terminals made of metal have been proposed in the recent years (for example, refer to Patent Literatures 1 to 3). In the connection method using the direct bonding technique, not only connection terminals but also insulating layers disposed around the connection terminals are bonded to each other. As the insulating layers, an inorganic insulating material such as silicon oxide is used.

### CITATION LIST

### Patent Literature

Patent Literature 1: Specification of U.S. Patent Application Publication No. 2020/0135636

Patent Literature 2: Specification of U.S. Patent Application Publication No. 2020/0135683

Patent Literature 3: Specification of U.S. Patent Application Publication No. 2020/0135684

### SUMMARY OF INVENTION

### Technical Problem

In a direct bonding technique using an inorganic insulating material as insulating layers, a defect in bonding between the insulating layers may occur due to the influence of cutting scrap (debris) or surface irregularities generated during a step such as dicing. In addition, in order to use an inorganic insulating material as insulating layers, it is necessary to apply expensive semiconductor processing steps for wiring formation and via formation, and the manufacturing cost of a semiconductor device tends to increase. Therefore, it has been considered that a direct bonding technique using an organic insulating material of resin material or the like, which is softer and cheaper than an inorganic material, as insulating layers, is used to embed debris or the like in the organic resin material or decreases surface irregularities during hot molding. Meanwhile, there is a case where bonding strength between organic insulating resin materials is lower than bonding strength between inorganic insulating materials. It is desirable to increase bonding strength between organic insulating layers while reducing manufacturing cost.

### Solution to Problem

The present disclosure provides a method for manufacturing a laminate as one aspect. The method for manufacturing a laminate includes forming a first organic insulating layer including a first thermosetting resin and first inorganic oxide particles on a first support substrate, polishing a first surface of the first organic insulating layer to planarize the first surface, and bonding the polished first surface to a second surface of a second organic insulating layer including a second thermosetting resin and second inorganic oxide particles.

In the method for manufacturing a laminate, the first and second organic insulating layers include the thermosetting resins and the inorganic oxide particles, and the first and second organic insulating layers are attached to be bonded to each other. In this case, the thermosetting resins contained in the first and second organic insulating layers are bonded to each other, and the inorganic oxide particles contained in the first and second organic insulating layers are joined to each other. Accordingly, bonding strength between the first organic insulating layer and the second organic insulating layer can be further increased while reducing manufacturing cost. In a case where each of the organic insulating layer contains the inorganic oxide particles, the surface roughness thereof may become rough, however, in the present manufacturing method, at least one of the organic insulating layers is polished before bonding. Accordingly, sufficient accuracy when bonding is performed and bonding strength therebetween are ensured.

In the above method for manufacturing a laminate, the first organic insulating layer may be polished such that an arithmetic mean roughness of the first surface is 50 nm or less in the polishing of the first organic insulating layer. In this case, the accuracy when the first organic insulating layer is bonded to the second organic insulating layer and the bonding strength therebetween can be more reliably increased. The arithmetic mean roughness used here is an arithmetic mean roughness (Ra) defined in JIS B 0601-2001.

In the above method for manufacturing a laminate, a content of the first inorganic oxide particles with respect to a total volume of the first organic insulating layer may be 15% by volume to 70% by volume. In this case, the bonding strength between the first organic insulating layer and the second organic insulating layer can be further increased.

The above method for manufacturing a laminate may further include grinding the first organic insulating layer. In the polishing of the first organic insulating layer, the ground first surface of the first organic insulating layer may be polished. In a case where each of the organic insulating layers contains the inorganic oxide particles, when the insulating layers are ground to a predetermined thickness, the surface roughness thereof may become rough. However, in the present manufacturing method, at least one of the ground surfaces is polished Accordingly, sufficient accuracy when bonding is before bonding. performed and bonding strength therebetween are ensured.

The above method for manufacturing a laminate may further include forming the second organic insulating layer including the second thermosetting resin and the second inorganic oxide particles on a second support substrate, and polishing the second surface of the second organic insulating layer to planarize the second surface. In this manufacturing method, the planarized first surface is bonded to the planarized second surface in the bonding. In this case, the bonding strength between the first organic insulating layer and the second organic insulating layer can be further increased.

In the above method for manufacturing a laminate, the second organic insulating layer may be polished such that an arithmetic mean roughness of the second surface is 50 nm or less in the polishing of the second organic insulating layer. In this case, the accuracy when the second organic insulating layer is bonded to the first organic insulating layer and the bonding strength therebetween can be more reliably increased. The arithmetic mean roughness used here is an arithmetic mean roughness (Ra) defined in JIS B 0601-2001.

In the method for manufacturing a laminate, a content of the second inorganic oxide particles with respect to a total volume of the second organic insulating layer may be 15% by volume to 70% by volume. In this case, the bonding strength between the first organic insulating layer and the second organic insulating layer can be further increased.

The above method for manufacturing a laminate may further include grinding the second organic insulating layer. The ground second surface of the second organic insulating layer may be polished in the polishing of the second organic insulating layer. In a case where each of the organic insulating layers contains the inorganic oxide particles, when the insulating layers are ground to a predetermined thickness, the surface roughness thereof may become rough. However, in the present manufacturing method, the ground surface is polished before bonding. Accordingly, sufficient accuracy when bonding is performed and bonding strength therebetween are ensured.

The above method for manufacturing a laminate may further include forming a first wiring electrode on the first support substrate. In this manufacturing method, the first wiring electrode may be encapsulated with a first organic insulating material containing the first thermosetting resin and the first inorganic oxide particles in the forming of the first organic insulating layer. Accordingly, the first wiring electrode is protected by the first organic insulating material.

In the above method for manufacturing a laminate, the first organic insulating layer may be ground such that a connection terminal of the first wiring electrode is exposed from the first surface of the first organic insulating layer before the polishing of the first organic insulating layer. Accordingly, the first wiring electrode can be more reliably connected to other wiring electrodes and the like.

The above method for manufacturing a laminate may further include forming a second wiring electrode on a second support substrate, and forming the second organic insulating layer including the second thermosetting resin and the second inorganic oxide on the second support substrate such that the second wiring electrode is encapsulated with a second organic insulating material containing the second thermosetting resin and the second inorganic oxide particles. In this manufacturing method, when the first surface of the first organic insulating layer is bonded to the second surface of the second organic insulating layer, a connection terminal of the first wiring electrode may be joined to a connection terminal of the second wiring electrode in the bonding. In this case, the first connection terminal and the second connection terminal can be more reliably joined to each other.

The above method for manufacturing a laminate may further include disposing a first semiconductor chip on the first support substrate. In this manufacturing method, the first semiconductor chip may be encapsulated with a first organic insulating material including the first thermosetting resin and the first inorganic oxide particles in the forming of the first organic insulating layer. Accordingly, the first semiconductor chip is protected by the first organic insulating material.

In the above method for manufacturing a laminate, the first organic insulating layer may be ground such that a connection terminal of the first semiconductor chip is exposed from the first surface of the first organic insulating layer before the polishing of the first organic insulating layer. Accordingly, the first semiconductor chip can be more reliably connected to other semiconductor chips and the like.

The above method for manufacturing a laminate may further include disposing a second semiconductor chip on a second support substrate, and forming the second organic insulating layer including the second thermosetting resin and the second inorganic oxide on the second support substrate such that the second semiconductor chip is encapsulated with a second organic insulating material including the second thermosetting resin and the second inorganic oxide particles. In this manufacturing method, when the first surface of the first organic insulating layer is bonded to the second surface of the second organic insulating layer, a connection terminal of the first semiconductor chip may be joined to a connection terminal of the second semiconductor chip in the bonding. In this case, the first semiconductor chip and the second semiconductor chip can be more reliably joined to each other.

The present disclosure provides a laminate as another aspect. The laminate includes a first support substrate, a first organic insulating layer including a cured product of a first thermosetting resin and first inorganic oxide particles, the first organic insulating layer being formed on the first support substrate, and a second organic insulating layer including a cured product of a second thermosetting resin and second inorganic oxide particles, the second organic insulating layer being bonded to the first organic insulating layer.

In this laminate, the first and second organic insulating layers include the thermosetting resins and the inorganic oxide particles, and the first and second organic insulating layers are attached to be bonded to each other. In this case, the thermosetting resins contained in the first and second organic insulating layers are bonded to each other, and the inorganic oxide particles contained in the first and second organic insulating layers are joined to each other. Accordingly, the laminate in which bonding strength between the first organic insulating layer and the second organic insulating layer is increased while decreasing manufacturing cost can be obtained.

The above laminate may further include a semiconductor chip disposed either on the first support substrate or in the first support substrate.

The above laminate may further include a first wiring electrode connected to the semiconductor chip, at least a part of the first wiring electrode being disposed in the first organic insulating layer and a connection terminal of the first wiring electrode being exposed from a first surface of the first organic insulating layer to be bonded to the second organic insulating layer, and a second wiring electrode of which at least a part is disposed in the second organic insulating layer, and a connection terminal of which is exposed from a second surface of the second organic insulating layer to be bonded to the first organic insulating layer. In this laminate, the connection terminal of the first wiring electrode and the connection terminal of the second wiring electrode may be joined to each other. Accordingly, the laminate in which the connection terminals protected by the organic insulating layers are connected to each other can be obtained.

In the above laminate, at least a part of the semiconductor chip is disposed in the first organic insulating layer on the first support substrate, and a connection terminal of the semiconductor chip may be exposed from a first surface of the first organic insulating layer to be bonded to the second organic insulating layer.

In the above laminate, a content of the first inorganic oxide particles with respect to a total volume of the first organic insulating layer may be 15% by volume to 70% by volume. In this case, the laminate in which the bonding strength between the first organic insulating layer and the second organic insulating layer is further increased can be obtained. In this laminate, a content of the second inorganic oxide particles with respect to a total volume of the second organic insulating layer may be 15% by volume to 70% by volume.

In the above laminate, the first inorganic oxide particles and the second inorganic oxide particles may be joined to each other on a surface where the first organic insulating layer and the second organic insulating layer are bonded to each other. Accordingly, the laminate in which the bonding strength between the first organic insulating layer and the second organic insulating layer is more reliably increased can be obtained.

### Advantageous Effects of Invention

According to the present disclosure, it is possible to provide the laminate in which the bonding strength between the organic insulating layers is increased while decreasing manufacturing cost.

### BRIEF DESCRIPTION OF DRAWINGS

FIG. 1 is a cross-sectional view showing a semiconductor device according to a first embodiment of the present disclosure.

FIGS. 2(a) to (c) are views showing a method for manufacturing the semiconductor device shown in FIG. 1.

FIGS. 3(a) to (c) are views showing the method for manufacturing the semiconductor device shown in FIG. 1, and showing steps subsequent to those shown in FIG. 2.

FIGS. 4(a) to (c) are views showing the method for manufacturing the semiconductor device shown in FIG. 1, and showing steps subsequent to those shown in FIG. 3.

FIG. 5 is a plan view showing a surface of an organic insulating layer after being polished in the step shown in FIG. 4(c).

FIG. 6(a) is a cross-sectional view showing the organic insulating layer formed in the step shown in FIG. 4(a), and FIG. 6(b) is a cross-sectional view showing the organic insulating layer after being polished in the step shown in FIG. 4(c).

FIG. 7 is a view showing the method for manufacturing the semiconductor device shown in FIG. 1, and showing a step subsequent to those shown in FIG. 4.

FIG. 8 is a cross-sectional view showing a cross section of a semiconductor device in which the organic insulating layers are connected to each other in the step shown in FIG. 7.

FIGS. 9(a) to (c) are views showing a method for manufacturing a semiconductor device according to a second embodiment of the present disclosure.

FIG. 10 is a view showing the method for manufacturing a semiconductor device according to the second embodiment, and showing a step subsequent to those shown in FIG. 9.

FIG. 11 is a cross-sectional view showing a semiconductor device according to the second embodiment.

FIGS. 12(a) to (c) are views showing a method for manufacturing a semiconductor device according to a third embodiment of the present disclosure.

FIG. 13 is a cross-sectional view showing a semiconductor device according to the third embodiment.

### DESCRIPTION OF EMBODIMENTS

Hereinafter, embodiments according to present invention will be described in detail with reference to the drawings. In the following description, the same or equivalent portions are denoted by the same reference signs, and duplicate descriptions will be omitted. In addition, positional relationships such as up, down, left, right, and the like are, unless otherwise specified, based on positional relationships shown in the drawings. When terms such as “left”, “right”, “front”, “back”, “up”, “down”, “upward”, and “downward” are used in the description and claims of the present specification, the terms are intended for description purposes, and do not necessarily permanently refer to the relative positions. Furthermore, the dimensional ratios in the drawings are not limited to the ratios shown in the drawings.

In the present specification, the term “layer” includes not only the structure of a shape formed on the entire surface, but also the structure of a partially formed shape when observed in a plan view. In addition, in the present specification, the term “step” includes not only an independent step, but also a step as long as the intended actions of the step are achieved even when the step cannot be clearly distinguished from other steps. In addition, a numerical range indicated using “to” indicates a range including numerical values written before and after “to” as a minimum value and a maximum value, respectively.

### Structure of Semiconductor Device

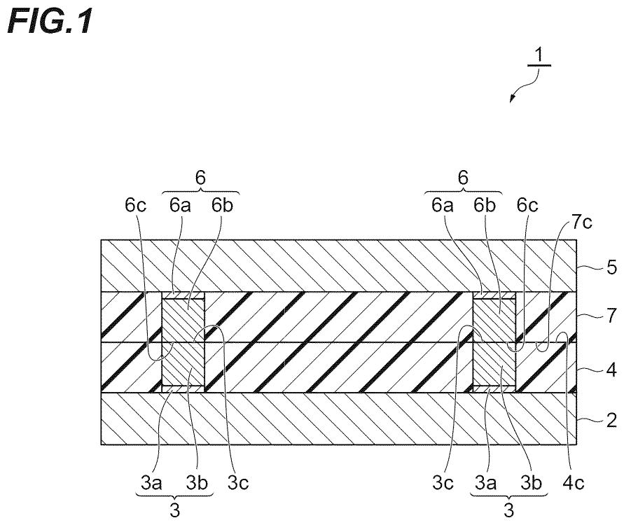

FIG. 1 is a cross-sectional view showing a semiconductor device according to a first embodiment of the present disclosure. As shown in FIG. 1, a semiconductor device 1 (laminate) includes a support substrate 2 (first support substrate), wiring electrodes 3, an organic insulating layer 4 (first organic insulating layer), a support substrate 5 (second support substrate), wiring electrodes 6, and an organic insulating layer 7 (second organic insulating layer).

The support substrate 2 and the support substrate 5 are, although not particularly limited, for example, a silicon plate, a glass plate, a SUS plate, a substrate containing glass cloth, an encapsulating resin substrate containing a semiconductor chip, or the like, and are substrates with high rigidity. At least one of the support substrate 2 and the support substrate 5 may be a substrate into which a semiconductor chip is built, or both the support substrate 2 and the support substrate 5 may be substrates into which semiconductor chips are built.

A thickness of the support substrate 2 and the support substrate 5 is, although not particularly limited, for example, 0.2 mm to 2.0 mm. By setting the support substrate 2 and the support substrate 5 to 0.2 mm or more, the handleability of the substrates can be improved. By setting the support substrate 2 and the support substrate 5 to 2.0 mm or less, material cost can be decreased. The support substrate 2 and the support substrate 5 may have a wafer shape or may have a panel shape. The support substrate 2 and the support substrate 5 may be, although not particularly limited in size, for example, a wafer having a diameter of 200 mm, a diameter of 300 mm, or a diameter of 450 mm, or a rectangular panel having a side of 300 mm to 700 mm.

The wiring electrodes 3 are microelectrodes formed on the support substrate 2. When the wiring electrodes 3 are formed by plating or the like, each of the wiring electrodes 3 may include a seed layer portion 3a and a plating portion 3b. The wiring electrodes 3 are formed from, for example, a conductive material such as copper (Cu). The wiring electrodes 3 may be electrode pins, and only two electrode pins are shown in FIG. 1; however, the number of the electrode pins may be 500 or more, and in the case of finer electrode pins, the number of the electrode pins may be 1000 to 10000 or more. In this case, a gap between the electrode pins may be 100 μm or less, and in the case of finer electrode pins, a gap between the electrode pins may be 20 μm to 100 μm.

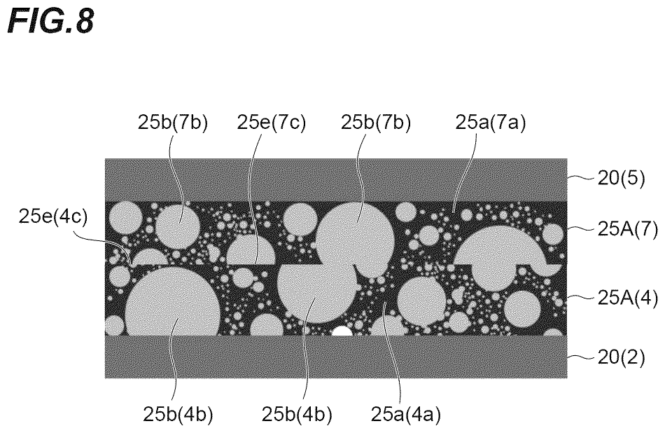

The organic insulating layer 4 is an insulating layer containing a cured product 4a of a thermosetting resin (a cured product of a first thermosetting resin) and inorganic oxide particles 4b (first inorganic oxide particles), and formed on the support substrate 2 (refer to FIG. 8). A thickness of the organic insulating layer 4 may be, for example, 10 Ξm to 300 μm. By setting the thickness of the organic insulating layer 4 to 10 μm or more, the insulation of the wiring electrodes 3 can be ensured, and a bonding force when the organic insulating layer 4 is bonded to the organic insulating layer 7 can be ensured. By setting the thickness of the organic insulating layer 4 to 300 μm or less, the overall thickness of the semiconductor device 1 can be made thin. The wiring electrodes 3 described above are protected by being embedded in the organic insulating layer 4 such that connection terminals 3c are exposed from a surface 4c (first surface) on a side that is bonded to the organic insulating layer 7 in the organic insulating layer 4.

The thermosetting resin used for the organic insulating layer 4 is not particularly limited, and may be a known thermosetting resin, for example, a thermosetting resin such as epoxy resin, acrylic resin, methacrylic resin, maleimide resin, phenolic resin, unsaturated imide resin, cyanate resin, isocyanate resin, benzoxazine resin, oxetane resin, amino resin, unsaturated polyester resin, allyl resin, dicyclopentadiene resin, silicone resin, triazine resin, or melamine resin. It is preferable that the thermosetting resin used for the organic insulating layer 4 is epoxy resin among these resins.

The inorganic oxide particles contained in the organic insulating layer 4 are not particularly limited, and known inorganic oxide particles, for example, silica (SiO₂), alumina (Al₂O₃), titania (TiO₂), tantalum oxide (Ta₂O₅), zirconia (ZrO₂), or zinc oxide (ZnO) can be used. A single type of inorganic oxide particles may be used, or two or more types may be used in combination. As one example, the inorganic oxide particles contained in the organic insulating layer 4 are silica.

A content of the inorganic oxide particles contained in the organic insulating layer 4 is, for example, 15% by volume to 70% by volume with respect to the total volume of the organic insulating layer 4. By setting the content of the inorganic oxide particles to 15% by volume or more of the total volume, the proportion of the cured product of the thermosetting resin contained in the organic insulating layer 4 is reduced, so that the coefficient of thermal expansion (CTE) of the organic insulating layer 4 can be decreased and warpage when heat is applied to the semiconductor device 1 can be reduced. By setting the content of the inorganic oxide particles to 70% by volume or less of the total volume, a sufficient bonding area between the thermosetting resins can be ensured, and bonding strength between the organic insulating layer 4 and the organic insulating layer 7 can be increased.

The wiring electrodes 6 are microelectrodes formed on the support substrate 5. When the wiring electrodes 6 are formed by plating or the like, the wiring electrode 6 may include a seed layer portion 6a and a plating portion 6b. The wiring electrodes 6 are formed from, similarly to the wiring electrodes 3, for example, a conductive material such as copper. The wiring electrodes 6 are electrodes provided to correspond to the wiring electrodes 3, and may be, similarly to the wiring electrodes 3, electrode pins. In FIG. 1, only two electrodes are shown as the wiring electrodes 6; however, the number of electrode pins may be 500 or more, and in the case of finer electrode pins, the number of electrode pins may be 1000 to 10000 or more. In this case, a gap between the electrode pins may be 100 μm or less, and in the case of finer electrode pins, a gap between the electrode pins may be 20 μm to 100 μm.

The organic insulating layer 7 is an insulating layer containing a cured product 7a of a thermosetting resin (a cured product of a second thermosetting resin) and inorganic oxide particles 7b (second inorganic oxide particles), and formed on the support substrate 5 (refer to FIG. 8). A thickness of the organic insulating layer 7 may be, similarly to the organic insulating layer 4, for example, 10 μm to 300 μm. The wiring electrodes 6 described above are protected by being embedded in the organic insulating layer 7 such that connection terminals 6c are exposed from a surface 7c (second surface) on a side that is bonded to the organic insulating layer 4 in the organic insulating layer 7.

In the semiconductor device 1, the wiring electrodes 3 and the wiring electrodes 6 are provided in the organic insulating layers 4 and 7, respectively, to correspond to each other, and the connection terminals 3c and the connection terminals 6c are joined to each other. In addition, the cured products 4a and 7a of the thermosetting resins contained in the organic insulating layers 4 and 7 are also bonded to each other, and the inorganic oxide particles 4b and 7b contained in the organic insulating layers 4 and 7 are also joined to each other. Particularly, the inorganic oxide particles 4b and 7b are strongly joined to each other due to joining between inorganic oxides, and connection between the organic insulating layers 4 and 7 in the semiconductor device 1 is made more reliable.

### Method for Manufacturing Semiconductor Device

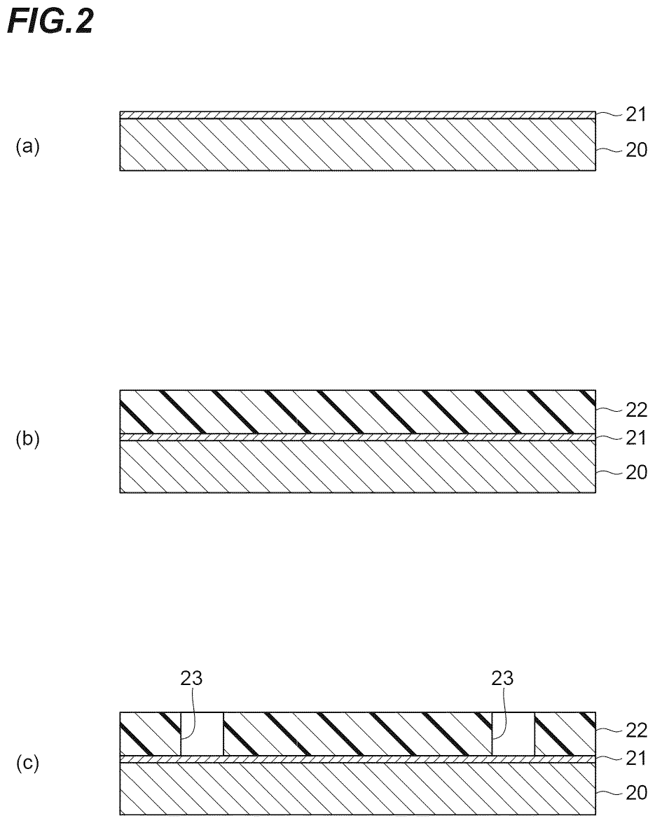

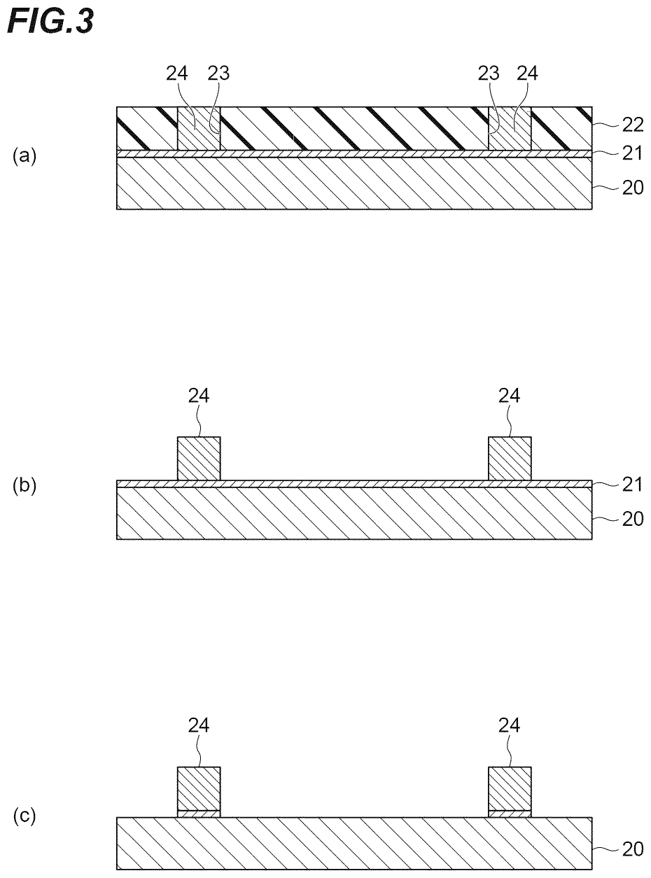

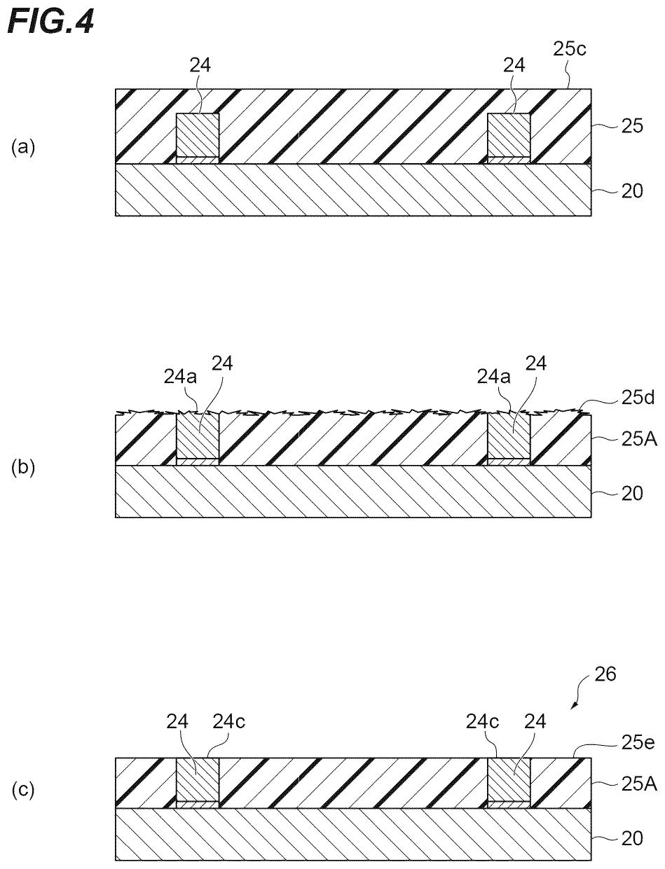

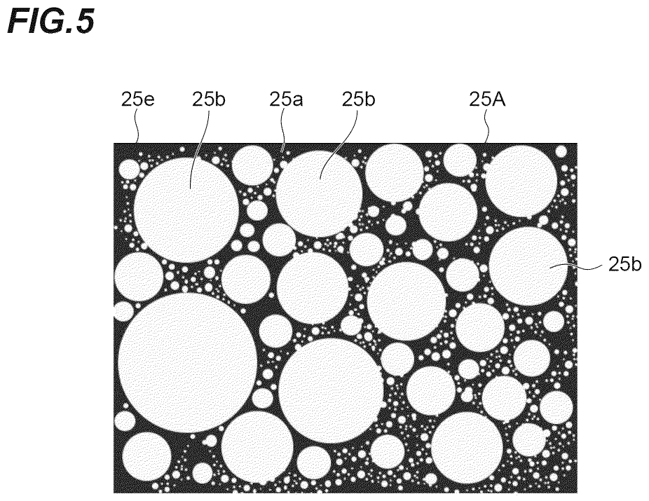

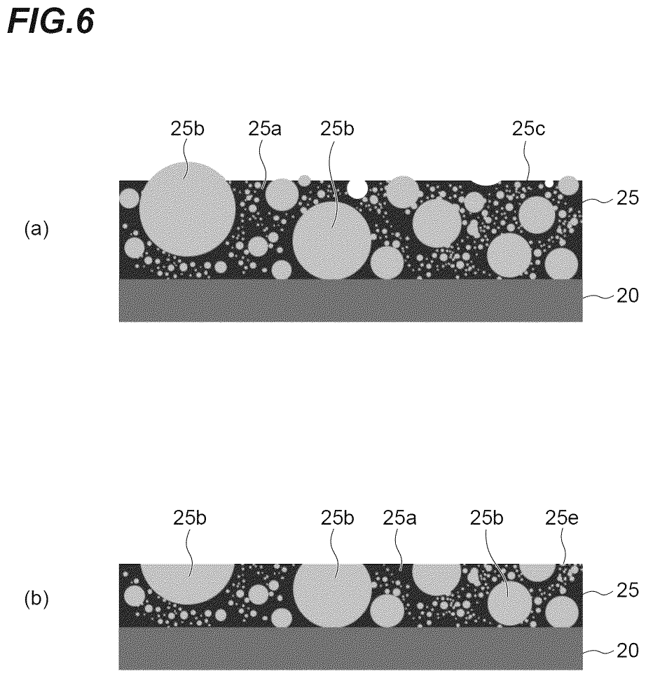

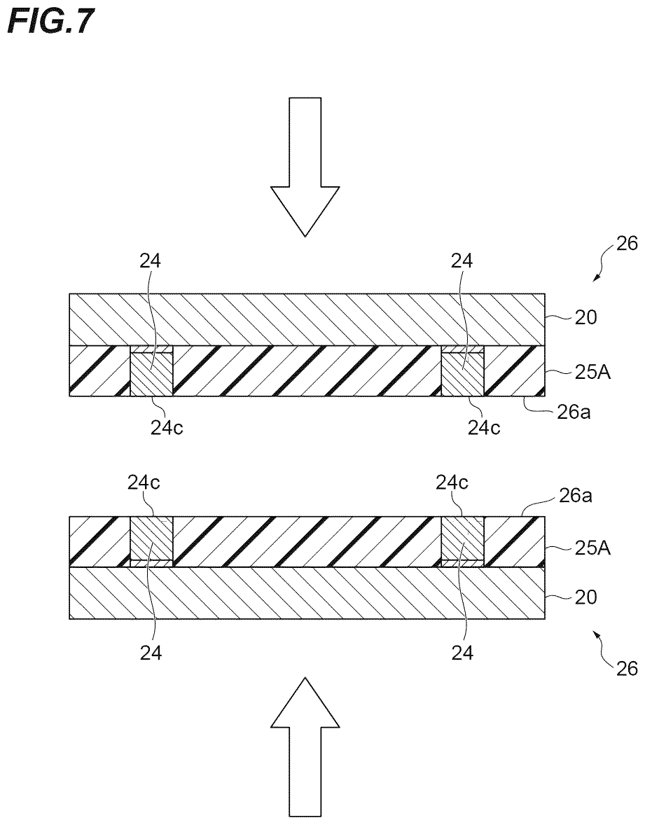

Next, a method for manufacturing the semiconductor device 1 (a method for manufacturing a laminate) will be described in order with reference to FIG. 2 to FIG. 8. FIGS. 2(a) to (c) are views showing the method for manufacturing the semiconductor device shown in FIG. 1. FIGS. 3(a) to (c) are views showing the method for manufacturing the semiconductor device shown in FIG. 1, and showing steps subsequent to those shown in FIG. 2. FIGS. 4(a) to (c) are views showing the method for manufacturing the semiconductor device shown in FIG. 1, and showing steps subsequent to those shown in FIG. 3. FIG. 5 is a plan view showing a surface of an organic insulating layer after being polished in the step shown in FIG. 4(c). FIG. 6(a) is a cross-sectional view showing the organic insulating layer formed in the step shown in FIG. 4(a), and FIG. 6(b) is a cross-sectional view showing the organic insulating layer after being polished in the step shown in FIG. 4(c). FIG. 7 is a view showing the method for manufacturing the semiconductor device shown in FIG. 1, and showing a step subsequent to those shown in FIG. 4. FIG. 8 is a cross-sectional view showing a cross section of a semiconductor device in which the organic insulating layers are connected to each other in the step shown in FIG. 7. For ease of description, an illustration of wiring electrodes is omitted in FIG. 5, FIG. 6, and FIG. 8.

First, as shown in FIG. 2(a), a seed layer 21 is formed on a support substrate 20 (a first support substrate, a second support substrate). The seed layer 21 is a portion that becomes a seed when an electrolytic copper plating is formed, which will be described later, and is formed from, for example, nickel or the like. The support substrate 20 is, although not particularly limited, for example, a silicon plate, a glass plate, a SUS plate, a substrate containing glass cloth, or an encapsulating resin substrate containing a semiconductor chip, or the like, and is a substrate with high rigidity. A thickness of the support substrate 20 is, although not particularly limited, for example, 0.2 mm to 2.0 mm. By setting the support substrate 20 to 0.2 mm or more, the handleability of the support substrate 20 can be improved. By setting the support substrate 20 to 2.0 mm or less, so that cost can be reduced, material cost is suppressed. The support substrate 20 may have a wafer shape or may have a panel shape. The support substrate 20 may be, although not particularly limited in size, for example, a wafer having a diameter of 200 mm, a diameter of 300 mm, or a diameter of 450 mm, or a rectangular panel having a side of 300 mm to 700 mm.

Subsequently, as shown in FIG. 2(b), a photosensitive resist is applied onto the seed layer 21 to form a resist layer 22. As the photosensitive resist, a known material can be used as appropriate. Thereafter, as shown in FIG. 2(c), exposure is performed to form vias 23 in regions corresponding to the wiring electrodes. Accordingly, the vias 23 through which the seed layer 21 is exposed is formed.

Subsequently, as shown in FIG. 3(a), wiring electrodes 24 (first wiring electrodes, second wiring electrodes) are formed on the seed layer 21 in the vias 23 by electrolytic copper plating. Thereafter, as shown in FIGS. 3(b) and (c), the resist layer 22 is peeled and removed, and portions of the seed layer 21 other than the wiring electrodes 24 are removed by etching. Through the above-described steps, the wiring electrodes 24 are formed on the support substrate 20. The method for forming the wiring electrodes 24 is not limited to this method, and the wiring electrodes 24 may be formed by other methods. The wiring electrodes 24 formed in such a manner can function as wiring pads, electrode pads, connection bumps, pillars, or the like.

Subsequently, as shown in FIG. 4(a), an organic insulating layer 25 is formed on the support substrate 20 such that the wiring electrodes 24 are encapsulated with an organic insulating material (a first organic insulating material, a second organic insulating material) containing a thermosetting resin (a first thermosetting resin, a second thermosetting resin) and inorganic oxide particles (first inorganic oxide particles, second inorganic oxide particles). At this time, the wiring electrodes 24 may be completely covered with the organic insulating material. During the formation, the organic insulating layer 25 containing the thermosetting resin and the inorganic oxide particles may be encapsulated by being formed in a mold using a compression or transfer molding machine. Alternatively, the organic insulating layer 25 containing the thermosetting resin and the inorganic oxide particles molded in a film shape may be encapsulated using a roll or pressure laminating machine. The support substrate 20 that is encapsulated and formed is heated using an oven, a hot plate, or the like. Accordingly, the organic insulating layer 25 containing the thermosetting resin and the inorganic oxide particles is formed on the support substrate 20. By the heating, the thermosetting resin of the organic insulating layer 25 may be completely cured, or may not be completely cured (for example, semi-cured, B-stage).

Materials for the thermosetting resin and the inorganic oxide particles included in the organic insulating layer 25 are, although not particularly limited, from the viewpoint of high rigidity and embeddability, encapsulating materials that can be formed in a mold, for example, by a compression or transfer molding machine. Alternatively, the materials included in the organic insulating layer 25 may be an encapsulating material, a build-up material, or a solder resist material molded in a film shape. In this case, from the viewpoint of preventing bubbles from being trapped, a film-shaped material may be laminated on the support substrate 20 under reduced pressure.

The thermosetting resin included in the organic insulating layer 25 is not particularly limited, and a known thermosetting resin can be used, and for example, epoxy resin, acrylic resin, methacrylic resin, maleimide resin, phenolic resin, unsaturated imide resin, cyanate resin, isocyanate resin, benzoxazine resin, oxetane resin, amino resin, unsaturated polyester resin, allyl resin, dicyclopentadiene resin, silicone resin, triazine resin, melamine resin, or the like can be used. It is preferable that the thermosetting resin used for the organic insulating layer 25 is epoxy resin among the above-described thermosetting resins.

The thermosetting resin may contain a crosslinking agent that performs crosslinking upon being heated. Although not particularly limited, a known crosslinking agent can be used, and for example, epoxy compound, isocyanate compound, phenolic resin, phenoxy resin, unsaturated polyester resin, alkyd resin, urethane resin, melamine resin, urea resin, guanamine resin, polyimide resin, polyamide resin, vinyl ester resin, diallyl phthalate resin, or the like may be used or two or more types may be used in combination.

The inorganic oxide particles included in the organic insulating layer 25 are not particularly limited, and known inorganic oxide particles can be used, and for example, such as silica (SiO₂), alumina (Al₂O₃), titania (TiO₂), tantalum oxide (Ta₂O₅), zirconia (ZrO₂), or zinc oxide (ZnO) can be used. A single type of inorganic oxide particles may be used, or two or more types may be used in combination. As one example, the inorganic oxide particles contained in the organic insulating layer 4 are silica.

A content of the inorganic oxide particles contained in the organic insulating layer 25 is, for example, 15% by volume to 70% by volume of the total volume of the organic insulating layer 25. By setting the content of the inorganic oxide particles to 15% by volume or more of the total volume, an increase in the coefficient of thermal expansion (CTE) of the entirety of the organic insulating layer 25 can be decreased, and warpage after an encapsulating step and a lamination step can be reduced. By setting the content of the inorganic oxide particles to 70% by volume or less of the total volume, when the polished surfaces of the substrates are compressed against each other while being heated in bonding to be described later, a bonding area between the thermosetting resins can be ensured, and sufficient bonding strength can be obtained.

The materials for the thermosetting resin and the inorganic oxide particles included in the organic insulating layer 25 may be, although not particularly limited, selected depending on a semiconductor package structure to be applied. For example, in the case of a semiconductor package in which a memory is laminated on an interposer substrate to which encapsulating materials are applied, when the encapsulating material included in the interposer and the encapsulating material formed to cover the memory chip are laminated, the encapsulating materials are laminated by applying the above-described manufacturing method.

A thickness of the organic insulating layer 25 is, for example, 10 μm to 400 μm. By setting the thickness of the organic insulating layer 25 to 10 μm or more, a bonding force when the organic insulating layer 25 is bonded to another organic insulating layer can be ensured. By setting the thickness of the organic insulating layer 25 to 400 μm or less, the warpage of the entirety of the substrate can be reduced, and the substrate can be easily adsorbed to a device in a subsequent grinding step.

Subsequently, as shown in FIG. 4(b), a surface 25c of the organic insulating layer 25 formed on the support substrate 20 is ground to cause the organic insulating layer 25 to have a predetermined thickness. In the grinding step, the surface 25c of the organic insulating layer 25 containing a thermosetting resin 25a and inorganic oxide particles 25b is exposed by grinding (refer to FIG. 5 and FIG. 6). The grinding is performed, for example, by a grinding technique using a grindstone rotating at high speed. Through the grinding step, surfaces 24a of the wiring electrodes 24 are exposed from a surface 25d of an organic insulating layer 25A. Regarding a surface roughness of the organic insulating layer 25A containing the thermosetting resin 25a and the inorganic oxide particles 25b subjected to the grinding treatment, from the viewpoint of grinding variations in a subsequent polishing treatment, an arithmetic mean roughness Ra when measured at a magnification of 20 times using a laser microscope is 0.5 μm or less. In FIG. 4(b), a state where the surface 25d has a certain degree of roughness is shown in an emphasized manner. The arithmetic mean roughness Ra used here is an arithmetic mean roughness (Ra) defined in JIS B 0601-2001.

Subsequently, as shown in FIG. 4(c), the surface 25d of the organic insulating layer 25A containing the thermosetting resin 25a and the inorganic oxide particles 25b is polished and planarized by chemical mechanical polishing (CMP). In the polishing step, the surface 25d of the organic insulating layer 25A containing the thermosetting resin 25a and the inorganic oxide particles 25b is planarized. The polishing step is performed, for example, by polishing a portion to be polished (organic insulating layer 25A) on the support substrate 20 while supplying a polishing liquid to a gap between a polishing pad (polishing cloth) and the portion to be polished. Various polishing liquids can be used as the polishing liquid for CMP. The polishing liquids for CMP are classified according to the type of abrasive grains (polishing particles) contained therein, and examples of the abrasive grains are cerium oxide (ceria) particles, silicon oxide (silica) particles, aluminum oxide (alumina) particles, organic resin particles, or the like. From the viewpoint of polishing rate, for example, ceria-particles are applied as the abrasive grains.

Through such polishing, a surface of the surface 25d of the organic insulating layer 25A may be polished, so that the arithmetic mean roughness Ra of a surface 25e becomes 50 nm or less. By setting the arithmetic mean roughness Ra of the surface 25e of the organic insulating layer 25A to 50 nm or less, the degraining of fillers and insufficient grinding of the surfaces of the filler in the organic insulating layer 25A can be prevented. Voids can be prevented from occurring at a bonding interface between the organic insulating layers due to wear or the like of the surfaces 25e of the organic insulating layers 25A, and bonding between the organic insulating layers to be described later can be made more reliable. The arithmetic mean roughness Ra of the organic insulating layer 25A subjected to the polishing treatment may be 50 nm or less, and polishing or grinding may be performed by a method other than CMP. For example, grinding by a fly-cut method can be applied. A combination of the fly-cut method and etching or the like may be applied.

A thickness of the organic insulating layer 25A on which the above-described grinding and polishing steps are performed is, for example, 1 μm to 300 μm. By setting the thickness of the organic insulating layer 25A to 1 μm or more, the yield can be increased without excessively grinding the embedded wirings and electrodes. By setting the thickness of the organic insulating layer 25A to 300 μm or less, warpage of the entirety of the substrate is suppressed, and the occurrence of voids at a contact interface in a compression step to be described later, which makes compression impossible, can be prevented.

FIG. 5 shows one example of a plan view of the surface 25e of the organic insulating layer 25A after the above-described polishing step is performed. As shown in FIG. 5, the organic insulating layer 25A contains the thermosetting resin 25a and the inorganic oxide particles 25b. In the polishing step, a proportion of an area occupied by the inorganic oxide particles 25b on the surface of the organic insulating layer 25A subjected to the polishing treatment is, for example, 15% to 75% of the total area. By setting the proportion of the area occupied by the inorganic oxide particles 25b to 15% or more of the total area, an increase in the coefficient of thermal expansion (CTE) of the organic insulating layer 25A can be decreased, and warpage after the encapsulating configuration and the lamination step can be suppressed. By setting the proportion of the area occupied by the inorganic oxide particles 25b to 70% or less of the total area of the organic insulating layer 25A, when the polished surfaces of the organic insulating layers are compressed against each other while being heated in the bonding to be described later, a bonding area between the thermosetting resins can be ensured, and sufficient bonding strength can be obtained.

FIG. 6(a) is a cross-sectional view showing the organic insulating layer 25 when the organic insulating material is formed on the support substrate 20, and FIG. 6(b) is a cross-sectional view showing the organic insulating layer 25A after being ground and polished. As shown in FIGS. 6(a) and (b), through the grinding and polishing steps, the surface 25c of the organic insulating layer 25 can be cut and polished to a desired thickness. The inorganic oxide particles in the organic insulating layer 25 are also appropriately ground and polished. Through the above-described steps, an organic substrate 26 of which the surface is polished is formed. For example, a pair of the organic substrates 26 having such a configuration are formed and bonded to each other as shown in the following steps.

Subsequently, when the pair of organic substrates 26 of which the surfaces are planarized in the polishing step are prepared, as shown in FIG. 7, surfaces 26a of each of the organic substrates 26 are bonded to each other by compression. During the bonding, compression may be performed under a nitrogen atmosphere. By setting an oxygen concentration when the compression is performed to 1000 ppm or less, the surfaces of the wiring electrodes, the thermosetting resin, and the inorganic oxide particles on the surfaces 26a of the organic substrate 26 exposed by the polishing step can be prevented from being oxidized, and accordingly, poor bonding can be reduced.

In the bonding step, a heating temperature when the planarized organic insulating layers 25A are compressed against each other is, for example, 200° C. to 400° C. By setting the heating temperature during the compression to 200° C. or higher, insufficient melting of the resin and poor bonding between the wiring layers can be prevented, and the bonding strength between the organic insulating layers 25A can be increased. By setting the heating temperature during the compression to 400° C. or lower, the thermosetting resin and the like in the organic insulating layers 25A can be prevented from being decomposed, and bonding between the thermosetting resins can be made more reliable.

In the bonding step, an applied pressure when the organic insulating layers 25A planarized in the polishing step are compressed against each other is, for example, 5.0 MPa to 100 MPa. By setting the applied pressure to 5.0 MPa or more, the organic insulating layers 25A planarized by CMP can be brought into sufficient contact with each other even when being affected by warpage or the like, and sufficient bonding strength can be obtained. By setting the applied pressure to 100 MPa or less, the substrates planarized by CMP can be prevented from being damaged.

In the bonding step, additional heating after the compression may be further performed under a nitrogen atmosphere if necessary. A heating temperature after the compression is, for example, 250° C. to 400° C., and a heating time after the compression is, for example, 30 minutes to 180 minutes. By performing heating at a temperature of 250° C. or higher, the embedded wiring electrodes 24 can be firmly joined to each other by metal bonding. By setting the heating temperature to 400° C. or lower, the resin component of the organic insulating layers 25A can be prevented from being decomposed due to heat. The thermosetting resin in the organic insulating layers 25A is completely cured by the additional heating or heating during the compression. Through the above-described steps, the semiconductor device 1 having the configuration shown in FIG. 1 is formed.

The materials included in the thermosetting resin and the inorganic oxide particles of the pair of organic insulating layers 25A bonded to each other in the above-described bonding step may be the same. When the materials are the same, the bonding strength when the organic insulating layers 25A are bonded to each other can be easily increased. The materials included in the thermosetting resin and the inorganic oxide particles of the organic insulating layers 25A bonded to each other in the above-described bonding step may be different. When bonding the surfaces of the organic insulating layers 25A obtained by planarizing the organic insulating layer containing the thermosetting resin and the inorganic oxide particles by CMP, a combination of the materials included in the organic insulating layers, each containing the thermosetting resin and the inorganic oxide particles, on the two substrates to be bonded to each other can be selected, although not particularly limited, depending on the semiconductor package structure to be applied. For example, when the present invention is applied to a semiconductor package assuming a 2.1 D package structure in which a fine wiring layer is formed on the organic insulating layer 25A, or a structure in which semiconductor chips mounted on a substrate can be connected to each other with high density using a bridge chip embedded in a cavity formed in the organic insulating layer 25A, a solder resist material or a build-up material on an organic substrate side and an encapsulating material covering the semiconductor chips are laminated by applying the above-described manufacturing method.

As described above, according to the method for manufacturing the semiconductor device according to the present embodiment, each of the organic insulating layers 25A to be bonded to each other contains the thermosetting resin 25a and the inorganic oxide particles 25b, and the organic insulating layers 25A are attached to be bonded to each other. In this case, the thermosetting resins 25a contained in the organic insulating layers 25A are bonded to each other, and the inorganic oxide particles 25b contained in the organic insulating layers 25A are joined to each other (refer to FIG. 8). Accordingly, the bonding strength between the organic insulating layers 25A can be further increased while decreasing manufacturing cost. In a case where each of the organic insulating layers 25A contains the inorganic oxide particles 25b, when the insulating layers are ground to a predetermined thickness, the surface roughness of the insulating layers may become rough. However, in the present manufacturing method, at least one of the organic insulating layers 25 and 25A is polished before bonding. Accordingly, sufficient accuracy when bonding is performed and bonding strength therebetween are ensured.

In the method for manufacturing the semiconductor device according to the present embodiment, the organic insulating layer 25A may be polished such that the arithmetic mean roughness Ra of the surface 25e of the organic insulating layer 25A is 50 nm or less in the step of polishing the organic insulating layer 25A. In this case, the accuracy when the organic insulating layer 25A is bonded to another corresponding organic insulating layer 25A and the bonding strength therebetween can be more reliably increased.

In the method for manufacturing the semiconductor device according to the present embodiment, the content of the inorganic oxide particles 25b with respect to the total volume of the organic insulating layer 25A may be 15% by volume to 70% by volume. In this case, bonding strength between the organic insulating layers 25A can be further increased.

In the method for manufacturing the semiconductor device according to the present embodiment, the wiring electrodes 24 are encapsulated with the organic insulating material containing the thermosetting resin 25a and the inorganic oxide particles 25b in the step of forming the organic insulating layer 25A. Accordingly, the wiring electrodes 24 are protected by the organic insulating material.

In the method for manufacturing the semiconductor device according to the present embodiment, the organic insulating layer 25A is ground such that connection terminals 24c of the wiring electrodes 24 are exposed from the surface 25d of the organic insulating layer 25A in the step of grinding the organic insulating layer 25A. Accordingly, the wiring electrodes 24 can be more reliably connected to other wiring electrodes 24 and the like.

### Second Embodiment

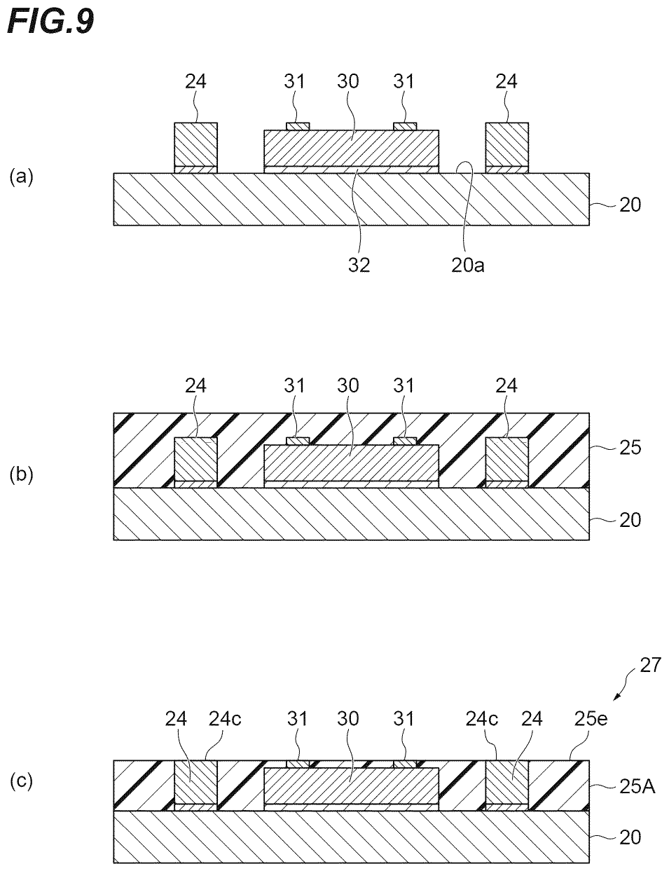

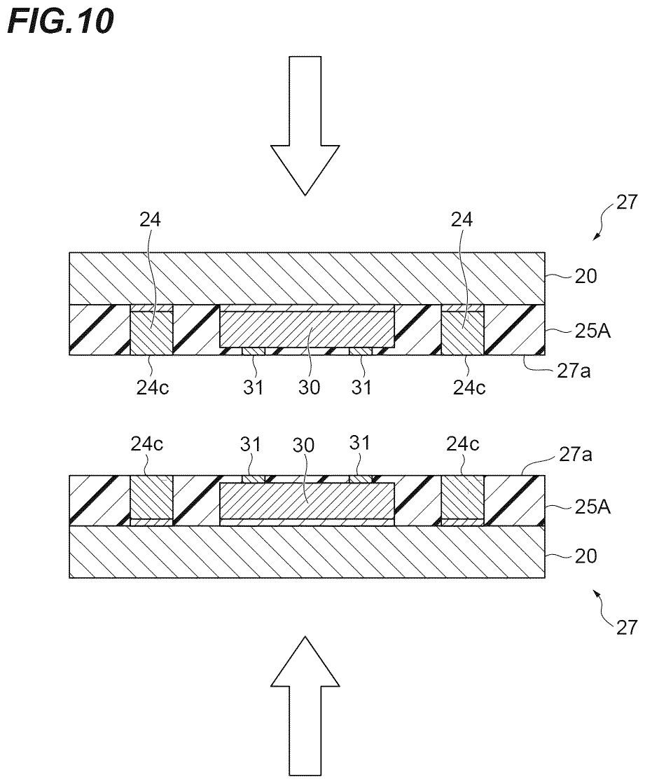

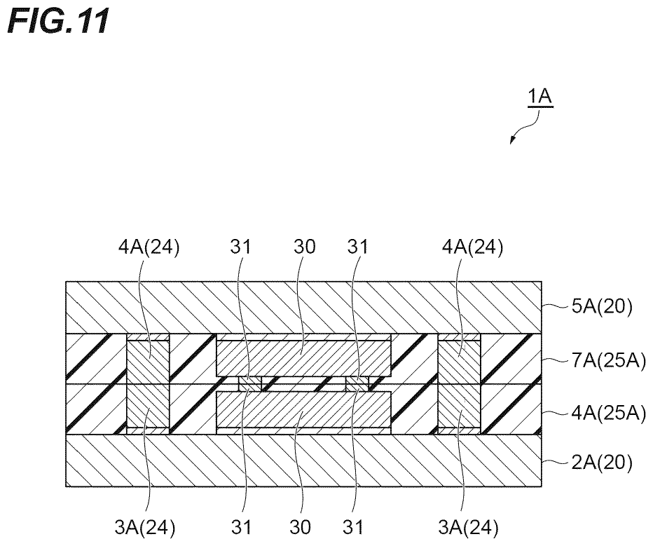

Next, a method for manufacturing a semiconductor device (a method for manufacturing a laminate) and a semiconductor device (laminate) according to a second embodiment of the present disclosure will be described with reference to FIG. 9 to FIG. 11. In the following description, differences from the first embodiment will be mainly described, and descriptions that are the same as or overlap with those of the first embodiment may be omitted. FIGS. 9(a) to (c) are views showing the method for manufacturing a semiconductor device according to the second embodiment of the present disclosure. FIG. 10 is a view showing a method for manufacturing a semiconductor device according to the second embodiment, and showing a step subsequent to those shown in FIG. 9. FIG. 11 is a cross-sectional view showing the semiconductor device according to the second embodiment.

As shown in FIG. 9(a), in the method for manufacturing a semiconductor device according to the second embodiment, a semiconductor chip 30 (a first semiconductor chip, a second semiconductor chip) is disposed at a predetermined location on the support substrate 20 (between the wiring electrodes 24 in the example shown in the drawing) in a member in which the wiring electrodes 24 are provided on the support substrate 20. More specifically, the semiconductor chip 30 is disposed on the support substrate 20 using an adhesive 32 such that connection terminals 31 of the semiconductor chip 30 face upward, namely, face a side opposite to the support substrate 20. At this time, the semiconductor chip 30 may be disposed such that heights of the connection terminals 31 of the semiconductor chip 30 and the connection terminals 24c of the wiring electrodes 24 substantially coincide with each other.

Subsequently, as shown in FIG. 9(b), the organic insulating layer 25 is formed on the support substrate 20 such that the wiring electrodes 24 and the semiconductor chip 30 are encapsulated with an organic insulating material containing the thermosetting resin 25a and the inorganic oxide particles 25b. At this time, the wiring electrodes 24 and the semiconductor chip 30 may be completely covered with the organic insulating material. It is preferable that the organic insulating layer 25 has a thickness sufficient to dispose a main body of the semiconductor chip 30 and wirings in the organic insulating layer 25.

Subsequently, as shown in FIG. 9(c), the grinding step and the polishing step of the first embodiment are performed. Various conditions for the grinding step and the polishing step can be the same as those in the first embodiment. However, in the second embodiment, during the grinding step, not only the connection terminals 24c of the wiring electrodes 24 but also the connection terminals 31 of the semiconductor chip 30 are exposed to the outside from the organic insulating layer 25A. In this case, the arithmetic mean roughness Ra of the organic insulating layer 25A may be, similarly to the first embodiment, 50 nm or less. The content of the inorganic oxide particles 25b contained in the organic insulating layers 25 and 25A subjected to the grinding step and the polishing treatment is, similarly to the first embodiment, for example, 15% by volume to 70% by volume of the total volume of the organic insulating layers 25 and 25A. The proportion of the area occupied by the inorganic oxide particles 25b on the surface 25e of the organic insulating layer 25A is, similarly to the first embodiment, for example, 15% to 75% of the total area. Through the above-described steps, an organic substrate 27 in which the semiconductor chip 30 is disposed on the support substrate 20 can be obtained.

Subsequently, when a pair of the organic substrates 27 of which the surfaces are planarized in the polishing step are prepared, as shown in FIG. 10, surfaces 27a of the organic substrates 27 are bonded to each other by compression. Conditions for the bonding can be the same as those in the first embodiment. During the bonding, similarly to the first embodiment, the organic insulating layers 25A are connected to each other, and the connection terminals 24c of the wiring electrodes 24 are joined to each other. In addition, the connection terminals 31 of the semiconductor chips 30 are further joined to each other, in the manufacturing method according to the second embodiment.

Through the above-described steps, as shown in FIG. 11, a semiconductor device 1A into which the semiconductor chips 30 are built is manufactured. As shown in FIG. 11, the semiconductor device 1A includes a support substrate 2A, wiring electrodes 3A, an organic insulating layer 4A, a support substrate 5A, wiring electrodes 6A, an organic insulating layer 7A, and the semiconductor chips 30.

As described above, in the method for manufacturing a semiconductor device according to the present embodiment, similarly to the first embodiment, each of the organic insulating layers 25A to be bonded to each other contains the thermosetting resin 25a and the inorganic oxide particles 25b, and the organic insulating layers 25A are attached to be bonded to each other. In this case, the thermosetting resins 25a contained in the organic insulating layers 25A are bonded to each other, and the inorganic oxide particles 25b contained in the organic insulating layers 25A are joined to each other (refer to FIG. 8). Accordingly, the bonding strength between the organic insulating layers 25A can be further increased while decreasing manufacturing cost. Other actions and effects are also the same as those of the first embodiment.

### Third Embodiment

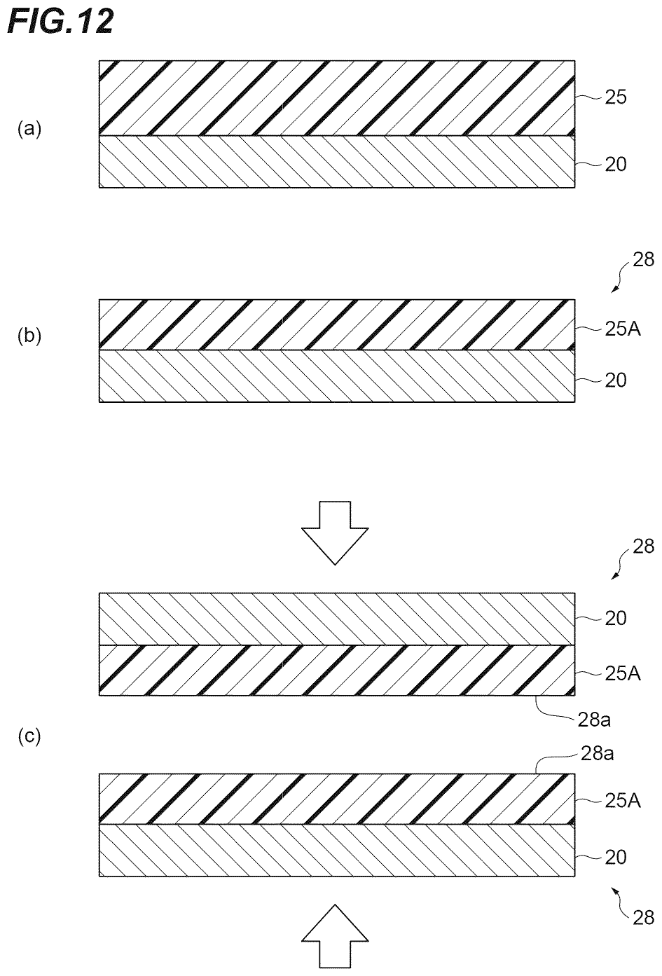

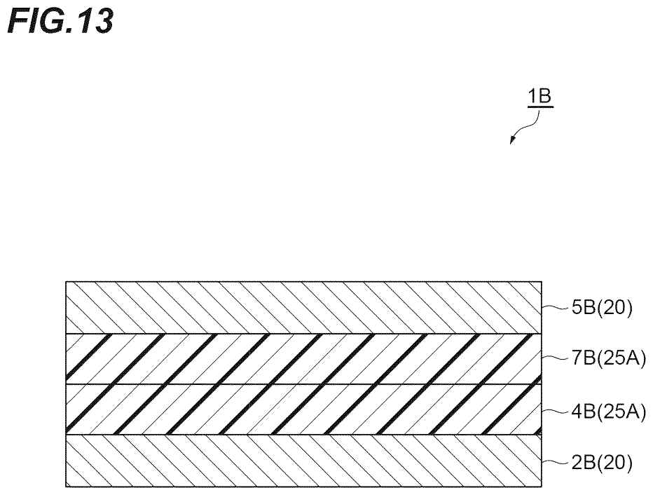

Next, a method for manufacturing a semiconductor device (a method for manufacturing a laminate) and a semiconductor device (laminate) according to a third embodiment of the present disclosure will be described with reference to FIG. 12 and FIG. 13. In the following description, differences from the first embodiment will be mainly described, and descriptions that are the same as or overlap with those of the first embodiment may be omitted. FIGS. 12(a) to (c) are views showing the method for manufacturing a semiconductor device according to the third embodiment of the present disclosure. FIG. 13 is a cross-sectional view showing the semiconductor device according to the third embodiment.

As shown in FIG. 12(a), in the method for manufacturing a semiconductor device according to the third embodiment, the organic insulating layer 25 is formed on the support substrate 20 using an organic insulating material containing the thermosetting resin 25a and the inorganic oxide particles 25b.

Subsequently, as shown in FIG. 12(b), the grinding step and the polishing step of the first embodiment are performed. Various conditions for the grinding step and the polishing step can be the same as those in the first embodiment. In this case, the arithmetic mean roughness Ra of the organic insulating layer 25A may be, similarly to the first embodiment, 50 nm or less. The content of the inorganic oxide particles 25b contained in the organic insulating layers 25 and 25A subjected to the grinding step and the polishing treatment is, similarly to the first embodiment, for example, 15% by volume to 70% by volume of the total volume of the organic insulating layers 25 and 25A. The proportion of the area occupied by the inorganic oxide particles 25b on the surface 25e of the organic insulating layer 25A is, similarly to the first embodiment, for example, 15% to 75% of the total area. Through the above-described steps, an organic substrate 28 in which the organic insulating layer 25A containing the inorganic oxide particles is disposed on the support substrate 20 can be obtained.

Subsequently, when a pair of the organic substrates 28 of which the surfaces are planarized in the polishing step are prepared, as shown in FIG. 12(c), surfaces 28a of the organic substrates 28 are bonded to each other by compression. Conditions for the bonding can be the same as those in the first embodiment.

Through the above-described steps, as shown in FIG. 13, a semiconductor device 1B is manufactured. As shown in FIG. 13, the semiconductor device 1B includes a support substrate 2B, an organic insulating layer 4B, a support substrate 5B, and an organic insulating layer 7B. In the semiconductor device 1B, a semiconductor chip may be built into at least one of the support substrate 2B and the support substrate 5B, or a semiconductor chip may be mounted outside at least one of the support substrate 2B and the support substrate 5B.

As described above, in the method for manufacturing a semiconductor device according to the present embodiment, similarly to the first embodiment, each of the organic insulating layers 25A to be bonded to each other contains the thermosetting resin 25a and the inorganic oxide particles 25b, and the organic insulating layers 25A are attached to be bonded to each other. In this case, the thermosetting resins 25a contained in the organic insulating layers 25A are bonded to each other, and the inorganic oxide particles 25b contained in the organic insulating layers 25A are joined to each other (refer to FIG. 8). Accordingly, the bonding strength between the organic insulating layers 25A can be further increased while decreasing manufacturing cost. Other actions and effects are also the same as those of the first embodiment.

The embodiments of the present disclosure have been described above; however, the present invention is not limited to the above-described embodiments, and may be modified as appropriate without departing from the concept of the present invention. For example, in the second embodiment, both the organic substrates 27 include the semiconductor chips 30; however, the configuration may be such that one organic substrate 27 includes the semiconductor chip 30 and the other organic substrate 27 does not include the semiconductor chip 30. In addition, the configurations of the first to third embodiments may be combined as appropriate.

### REFERENCE SIGNS LIST

1, 1A, 1B: semiconductor device (laminate), 2, 2A, 2B: support substrate (first support substrate), 3, 3A: wiring electrode (first wiring electrode), 3c: connection terminal, 4, 4A, 4B: organic insulating layer (first organic insulating layer), 4c: surface (first surface), 5, 5A, 5B: support substrate (second support substrate), 6, 6A: wiring electrode (second wiring electrode), 6c: connection terminal, 7, 7A, 7B: organic insulating layer (second organic insulating layer), 7c: surface (second surface), 20: support substrate (first support substrate, second support substrate), 24: wiring electrode (first wiring electrode, second wiring electrode), 24c: connection terminal, 25, 25A: organic insulating layer, 25a: thermosetting resin (first thermosetting resin, second thermosetting resin), 25b: inorganic oxide particle (first inorganic oxide particle, second inorganic oxide particle), 25c, 25d, 25e: surface (first surface, second surface), 30: semiconductor chip, 31: connection terminal.

1. A method for manufacturing a laminate, comprising:
forming a first organic insulating layer including a first thermosetting resin and first inorganic oxide particles on a first support substrate;
polishing a first surface of the first organic insulating layer to planarize the first surface; and
bonding the polished first surface to a second surface of a second organic insulating layer including a second thermosetting resin and second inorganic oxide particles.

2. The method for manufacturing a laminate according to claim 1,
wherein in the polishing of the first organic insulating layer, the first organic insulating layer is polished such that an arithmetic mean roughness of the first surface is 50 nm or less.

3. The method for manufacturing a laminate according to claim 1 or 2,
wherein a content of the first inorganic oxide particles with respect to a total volume of the first organic insulating layer is 15% by volume to 70% by volume.

4. The method for manufacturing a laminate according to any one of claims 1 to 3, further comprising:
grinding the first organic insulating layer,
wherein in the polishing of the first organic insulating layer, the ground first surface of the first organic insulating layer is polished.

5. The method for manufacturing a laminate according to any one of claims 1 to 4, further comprising:
forming the second organic insulating layer including the second thermosetting resin and the second inorganic oxide particles on a second support substrate; and
polishing the second surface of the second organic insulating layer to planarize the second surface,
wherein in the bonding, the planarized first surface is bonded to the planarized second surface.

6. The method for manufacturing a laminate according to claim 5,
wherein in the polishing of the second organic insulating layer, the second organic insulating layer is polished such that an arithmetic mean roughness of the second surface is 50 nm or less.

7. The method for manufacturing a laminate according to claim 5 or 6,
wherein a content of the second inorganic oxide particles with respect to a total volume of the second organic insulating layer is 15% by volume to 70% by volume.

8. The method for manufacturing a laminate according to any one of claims 5 to 7, further comprising:
grinding the second organic insulating layer,
wherein in the polishing of the second organic insulating layer, the ground second surface of the second organic insulating layer is polished.

9. The method for manufacturing a laminate according to any one of claims 1 to 8, further comprising:
forming a first wiring electrode on the first support substrate,
wherein in the forming of the first organic insulating layer, the first wiring electrode is encapsulated with a first organic insulating material including the first thermosetting resin and the first inorganic oxide particles.

10. The method for manufacturing a laminate according to claim 9,
wherein before the polishing of the first organic insulating layer, the first organic insulating layer is ground such that a connection terminal of the first wiring electrode is exposed from the first surface of the first organic insulating layer.

11. The method for manufacturing a laminate according to claim 9 or 10, further comprising:
forming a second wiring electrode on a second support substrate; and
forming the second organic insulating layer including the second thermosetting resin and the second inorganic oxide on the second support substrate such that the second wiring electrode is encapsulated with a second organic insulating material including the second thermosetting resin and the second inorganic oxide particles,
wherein in the bonding, when the first surface of the first organic insulating layer is bonded to the second surface of the second organic insulating layer, a connection terminal of the first wiring electrode is joined to a connection terminal of the second wiring electrode.

12. The method for manufacturing a laminate according to any one of claims 1 to 11, further comprising:
disposing a first semiconductor chip on the first support substrate,
wherein in the forming of the first organic insulating layer, the first semiconductor chip is encapsulated with a first organic insulating material including the first thermosetting resin and the first inorganic oxide particles.

13. The method for manufacturing a laminate according to claim 12,
wherein before the polishing of the first organic insulating layer, the first organic insulating layer is ground such that a connection terminal of the first semiconductor chip is exposed from the first surface of the first organic insulating layer.

14. The method for manufacturing a laminate according to claim 12 or 13, further comprising:
disposing a second semiconductor chip on a second support substrate; and
forming the second organic insulating layer including the second thermosetting resin and the second inorganic oxide on the second support substrate such that the second semiconductor chip is encapsulated with the second organic insulating material including the second thermosetting resin and the second inorganic oxide particles,
wherein in the bonding, when the first surface of the first organic insulating layer is bonded to the second surface of the second organic insulating layer, a connection terminal of the first semiconductor chip is joined to a connection terminal of the second semiconductor chip.

15. A laminate comprising:
a first support substrate;
a first organic insulating layer including a cured product of a first thermosetting resin and first inorganic oxide particles, the first organic insulating layer being formed on the first support substrate; and
a second organic insulating layer including a cured product of a second thermosetting resin and second inorganic oxide particles, the second organic insulating layer being bonded to the first organic insulating layer.

16. The laminate according to claim 15, further comprising:
a semiconductor chip disposed either on the first support substrate or in the first support substrate.

17. The laminate according to claim 16, further comprising:
a first wiring electrode connected to the semiconductor chip, at least a part of the first wiring electrode being disposed in the first organic insulating layer and a connection terminal of the first wiring electrode being exposed from a first surface of the first organic insulating layer to be bonded to the second organic insulating layer; and
a second wiring electrode of which at least a part is disposed in the second organic insulating layer, and a connection terminal of which is exposed from a second surface of the second organic insulating layer to be bonded to the first organic insulating layer,
wherein the connection terminal of the first wiring electrode and the connection terminal of the second wiring electrode are joined to each other.

18. The laminate according to claim 16 or 17,
wherein at least a part of the semiconductor chip is disposed in the first organic insulating layer on the first support substrate, and a connection terminal of the semiconductor chip is exposed from a first surface of the first organic insulating layer to be bonded to the second organic insulating layer.

19. The laminate according to any one of claims 15 to 18,
wherein a content of the first inorganic oxide particles with respect to a total volume of the first organic insulating layer is 15% by volume to 70% by volume.

20. The laminate according to any one of claims 15 to 19,
wherein the first inorganic oxide particles and the second inorganic oxide particles are joined to each other on a surface where the first organic insulating layer and the second organic insulating layer are bonded to each other.
